(19) United States
(12) Patent Application Publication
(10) Pub. No.: US 2017/0300806 A1
(43) Pub. Date: Oct. 19, 2017

(54) NEUROMORPHIC DEVICE INCLUDING SYNAPSES HAVING FIXED RESISTANCE VALUES

(71) Applicant: SK hynix Inc., Icheon (KR)

(72) Inventor: Hyung-Dong LEE, Hwaseong (KR)

(21) Appl. No.: 15/487,281

(22) Filed: Apr. 13, 2017

Related U.S. Application Data
(60) Provisional application No. 62/322,548, filed on Apr. 14, 2016.

(30) Foreign Application Priority Data
Dec. 13, 2016 (KR) 10-2016-0169689

(51) Int. Cl. G06N 3/04; H01L 23/522; H01L 23/528; G06N 3/08

(52) U.S. Cl. CPC G06N 3/04; H01L 23/528; G06N 3/08; H01L 23/5226; H01L 23/5228

(57) ABSTRACT

A neuromorphic device may include: pre-synaptic neurons; row lines extending in a first direction from the pre-synaptic neurons, respectively; post-synaptic neurons; column lines extending in a second direction from the post-synaptic neurons, respectively, the second direction crossing the first direction; and synapses arranged in intersection regions between the row lines and the column lines. The synapses may include resistor interconnections having various fixed resistance values. The synapses may be programmed with at least one pattern based on the various fixed resistance values.

### CROSS-REFERENCE TO RELATED APPLICATIONS

The present application claims priority to U.S. Provisional Patent Application No. 62/322,548, filed on Apr. 14, 2016, and Korean Patent Application No. 10-2016-0169689, filed on Dec. 13, 2016, which are incorporated herein by reference in their entirety.

### BACKGROUND

### 1. Field

Exemplary embodiments of the present disclosure relate to a read-only neuromorphic device including synapses having fixed resistance values.

### 2. Description of the Related Art

Recently, much attention has been paid to neuromorphic technology, which uses chips that mimic the human brain. A neuromorphic device based on neuromorphic technology, for example, includes a plurality of pre-synaptic neurons, a plurality of post-synaptic neurons, and a plurality of synapses. The neuromorphic device outputs pulses or spikes having various levels, amplitudes, or times, according to learning states of the neuromorphic device. The neuromorphic device, which includes synapses having variable resistors to read and write data, has a complex circuit configuration. For example, the neuromorphic device includes address coding/decoding circuits and row and column drivers to designate a specific synapse during a potentiation or depression process for changing a synaptic weight. Furthermore, when the neuromorphic device has a multilayer structure, the neuromorphic device further includes peripheral circuits belonging to the respective layers. Therefore, the chip size of the neuromorphic device may be relatively large. Furthermore, since resistance values of the variable resistors may be changed by an electrical influence, data retention abilities of the synapses may be degraded.

### SUMMARY

Various embodiments are directed to synapses having fixed resistance values.

Also, various embodiments are directed to a neuromorphic device including synapses having fixed resistance values.

Also, various embodiments are directed to a neuromorphic device including a plurality of synapse layers having fixed resistance values.

In an embodiment, a neuromorphic device may include: pre-synaptic neurons; row lines extending in a first direction from the pre-synaptic neurons, respectively; post-synaptic neurons; column lines extending in a second direction from the post-synaptic neurons, respectively, the second direction crossing the first direction; and synapses arranged in intersection regions between the row lines and the column lines. The synapses may include resistor interconnections having various fixed resistance values, the synapses being programmed with at least one pattern based on the various fixed resistance values.

The various fixed resistance values may include at least four levels.

The resistor interconnections may be disposed in a substrate.

The synapses may include resistor interconnections that include conductive paths having different lengths, the different lengths respectively providing the various fixed resistance values.

The synapses may include resistor interconnections that contain ions doped at various concentrations, the various concentrations providing the various fixed resistance values.

The resistor interconnections may include silicon doped with N-type or P-type ions.

The resistor interconnections may be doped with N-type ions, the N-type ions including P (phosphorous) or As (arsenic) ions.

Each of the resistor interconnections may include one or more doping regions having different doping concentrations.

Each of the resistor interconnections may include one or more of a low-concentration doping region, a middle-concentration doping region, and a high-concentration doping region.

Each of the resistor interconnections may include one or more resistance regions having different conductivities.

Each of the resistance regions may include one of an intrinsic semiconductor region, a low-concentration doped semiconductor region, a high-concentration doped semiconductor region, a metal silicide region, a metal compound region, a metal alloy region, and a metal region.

Each of the resistor interconnections may be a silicon wiring, a metal silicide interconnection, or a metal interconnection.

Each of the synapses may further include a row contact and a column contact. The resistor interconnection may electrically connect the row contact and the column contact.

Each of the resistor interconnections may include a plurality of via plugs that are electrically coupled to each other.

The resistor interconnection may further include a plurality of pads that are alternately stacked with the plurality of via plugs.

The plurality of via plugs may provide the various fixed resistance levels by having different vertical alignments.

The plurality of via plugs may provide the various fixed resistance levels by having different horizontal thicknesses.

The post-synaptic neurons may include post-synaptic circuits that are electrically connected to the column lines, respectively, each of the post-synaptic neurons comprising an integrator and a comparator, the integrator having an input unit connected to a corresponding one of the column lines, the comparator receiving an output of the integrator.

The synapses coupled to one of the column lines may be programmed to store a different pattern from synapses coupled to another one of the column lines.

### BRIEF DESCRIPTION OF THE DRAWINGS

FIG. 1 is a block diagram conceptually illustrating a neuromorphic device in accordance with an embodiment.

FIGS. 2A to 5 are diagrams for describing a process of setting synapses having fixed resistance values in a neuromorphic device in accordance with an embodiment.

FIGS. 6A to 7F are diagrams illustrating methods for implementing synapses having fixed resistance values in accordance with various embodiments.

FIG. 8A is a conceptual cross-sectional view of synapses having fixed resistance values in accordance with an embodiment.

FIG. 8B illustrates layouts or plan views of synapses in accordance with various embodiments.

FIG. 9 is a block diagram conceptually illustrating a post-synaptic neuron in accordance with an embodiment.

FIGS. 10A and 10B are block diagrams conceptually illustrating multi-neuromorphic systems in accordance with embodiments.

FIG. 11 is a block diagram conceptually illustrating a pattern recognition system in accordance with an embodiment.

### DETAILED DESCRIPTION

Various embodiments will be described below in more detail with reference to the accompanying drawings. The inventive concepts may, however, be embodied in different forms and should not be construed as limited to the embodiments set forth herein. Rather, these embodiments are provided so that this disclosure will be thorough and complete, and will fully convey the scope of the inventive concepts to those skilled in the art.

Terms used in this specification are used to describe exemplary embodiments without limiting the inventive concepts. The terms of a singular form may include plural forms unless referred to the contrary. The meaning of ‘comprise’ and ‘comprising’ used in the specification specifies a component, step, operation, and/or element but does not exclude other components, steps, operations, and/or elements.

When one element is referred to as being ‘connected to’ or ‘coupled to’ another element, it may indicate that the former element is directly connected or coupled to the latter element or another element is interposed therebetween. On the other hand, when one element is referred to as being ‘directly connected to’ or ‘directly coupled to’ another element, it may indicate that no element is interposed therebetween. Here, ‘and/or’ may include each of described items and one or more combinations thereof.

The terms such as ‘below,’ ‘beneath,’ ‘lower,’ ‘above,’ and ‘upper,’ which are spatially relative terms, may be used to simply describe the correlation between one element or components and another element or other components as illustrated in the drawings. The spatially relative terms should be understood as terms including different directions of elements during use or operation, in addition to the directions illustrated in the drawings. For example, when an element illustrated in the drawings is turned over, an element referred to as being ‘below’ or ‘beneath’ another element may be placed above another element.

Throughout the specification, like reference numerals refer to the same elements. Therefore, although the same or similar reference numerals are not mentioned or described in the corresponding drawing, the reference numerals may be described with reference to other drawings. Furthermore, although elements are not represented by reference numerals, the elements may be described with reference to other drawings.

In this specification, ‘potentiating,’ ‘setting,’ ‘learning,’ and ‘training’ may be used as the same or similar terms, and ‘depressing,’ ‘resetting,’ and ‘initializing’ may be used as the same or similar terms. For example, an operation of lowering resistance values of synapses may be exemplified as potentiating, setting, learning, or training, and an operation of raising resistance values of synapses may be exemplified as depressing, resetting, or initializing. Furthermore, when a synapse learns, or is potentiated, set, or trained, a gradually increasing voltage/current may be outputted from the synapse because the conductivity of the synapse increases. On the other hand, when a synapse is depressed, reset, or initialized, a gradually decreasing voltage/current may be outputted from the synapse because the conductivity of the synapse decreases. For convenience of description, a data pattern, an electrical signal, a pulse, a spike, and a firing may be interpreted as having the same, similar, or a compatible meaning. Furthermore, a voltage and a current may be interpreted as having the same or a compatible meaning.

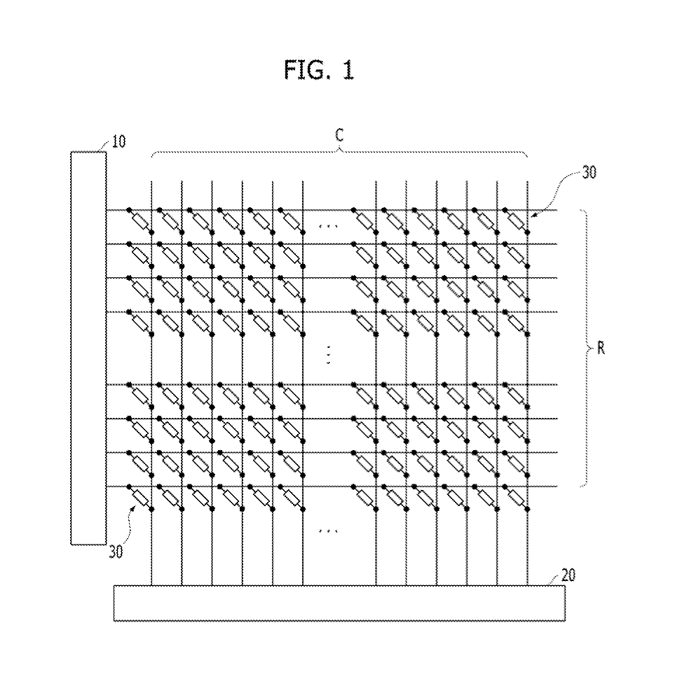

FIG. 1 is a block diagram conceptually illustrating a neuromorphic device in accordance with an embodiment. Referring to FIG. 1, the neuromorphic device may include a plurality of pre-synaptic neurons 10, a plurality of row lines R, a plurality of post-synaptic neurons 20, a plurality of column lines C, and a plurality of synapses 30. The row lines R may extend in a row direction from the respective pre-synaptic neurons 10, the column lines C may extend in a column direction from/to the respective post-synaptic neurons 20, and the plurality of synapses 30 may be arranged at the respective intersection regions between the row lines R and the column lines C.

The pre-synaptic neurons 10 may transmit internal input signals to the synapses 30 through the row lines R. The internal input signals may include data patterns.

The post-synaptic neurons 20 may receive internal output signals from the synapses 30 through the column lines C. The internal output signals may have information on data patterns registered, memorized, or saved in the synapses 30.

Each of the synapses 30 may include a resistive device having a fixed resistance value. Specifically, each of the synapses 30 may have a resistance value at one of multiple levels, for example, one of at least four levels. The multiple levels of resistance values may be interpreted as synaptic weights.

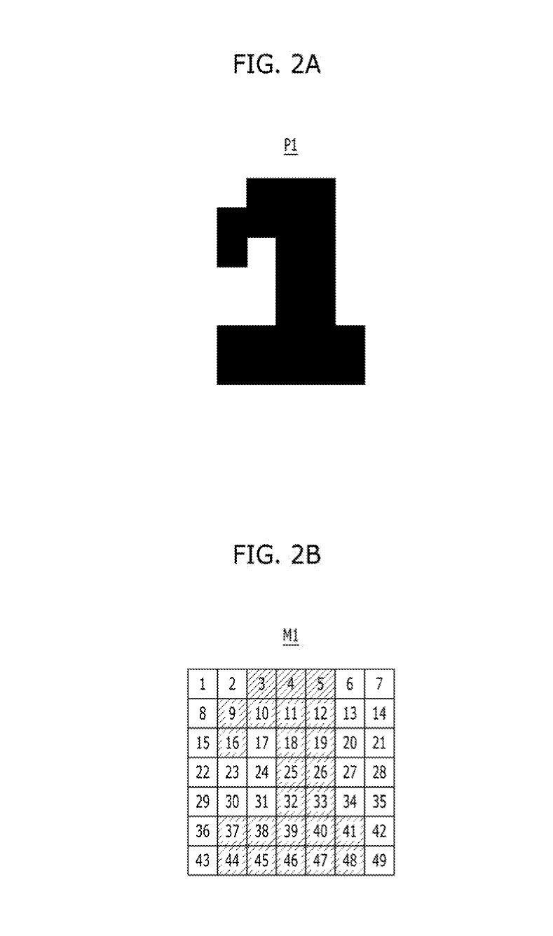

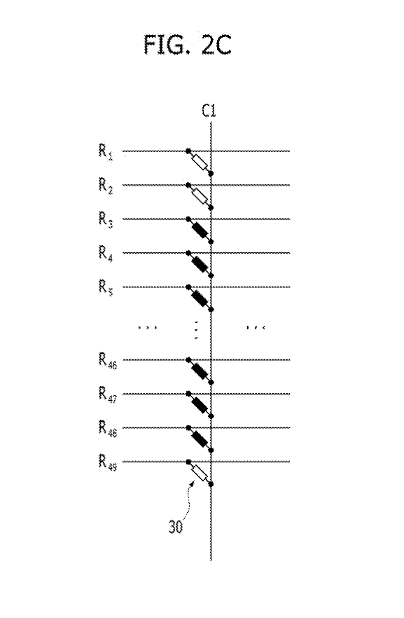

FIGS. 2A to 5 are diagrams for describing a process of setting synapses having fixed resistance values in a neuromorphic device in accordance with an embodiment. FIGS. 2A, 3A, and 4A illustrate various input patterns P1, P2, and P3, respectively. FIGS. 2B, 3B, and 4B illustrate synaptic weight maps M1, M2, and M3 obtained by computing the input patterns P1, P2, and P3, respectively, using software. FIGS. 2C, 3C, and 4C illustrate synapse columns C1, C2, and C3. The synapse columns C1, C2, and C3 include synapses set to fixed resistance values according to the synaptic weight maps M1, M2, and M3, respectively.

Referring to FIGS. 2A to 4C, the input patterns P1, P2, and P3 may be computed into the synaptic weight maps M1, M2, and M3 each having a 7×7 arrangement of cells; and the synapse columns C1, C2, and C3 may be programmed to have synapses set to fixed resistance values corresponding to the synaptic weights of the respective cells in the synaptic weight maps M1, M2, and M3, respectively. In order to promote understanding of the inventive concepts, the following descriptions may be based on the supposition that the input patterns P1 to P3 are black and white image patterns each representing a shape of a numeral “1.” Thus, it is assumed and described that each of the synaptic weights of the cells has information corresponding to a logic value ‘1’ or a logic value ‘0.’ However, embodiments are not limited thereto.

FIG. 2A illustrates the first input pattern P1, FIG. 2B illustrates the first synaptic weight map M1 obtained by computing the first input pattern P1, and FIG. 2C illustrates the first synapse column C1 including synapses set to fixed resistance values that correspond to synaptic weights of the first synaptic weight map M1.

Referring to FIGS. 2A and 2B, the first input pattern P1 may be separated into a 7×7 arrangement of cells, and computed into the first synaptic weight map M1, using software, an image processor, or the like. The first synaptic weight map M1 may include cells storing information of the logic value 1 and cells storing information of the logic value 0. The cells having the information of the logic value 1 may be hatched in FIG. 2B in order to indicate the first input pattern P1.

Referring to FIG. 2C, the first synapse column C1 may include synapses 30 which are programmed into fixed resistance values corresponding to the synaptic weights of the synaptic weight map M1 of FIG. 2B. Specifically, the synapses 30 arranged on the first synapse column C1 may be sequentially programmed to correspond to the cells of the first synaptic weight map M1. Cell numbers of the 7×7 (=49) cells of the first synaptic weight map M1 are analyzed and converted into numbers of row lines R₁ to R₄₉. Thus, the hatched cells in the first synaptic weight map M1, that is, the synapses 30 each having a synaptic weight of the logic value 1, are represented in black as shown in FIG. 2C. For example, the synapses 30 coupled to the row lines R₃ to R₅ and R₄₆ to R₄₈ in FIG. 2C, which are in black, correspond to the cells having cell numbers 3 to 5 and 46 to 48 in FIG. 2B. The cells having the cell numbers 3 to 5 and 46 to 48 are hatched in order to indicate the first input pattern P1.

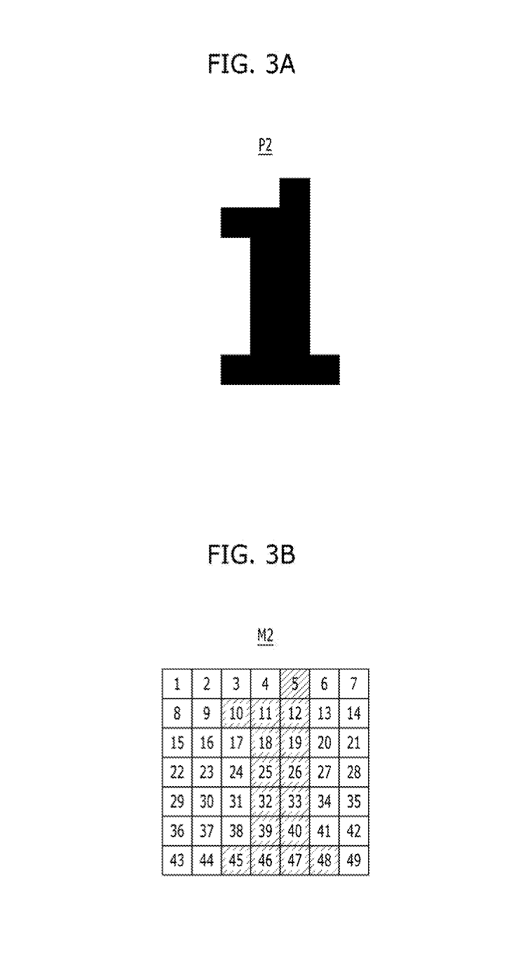

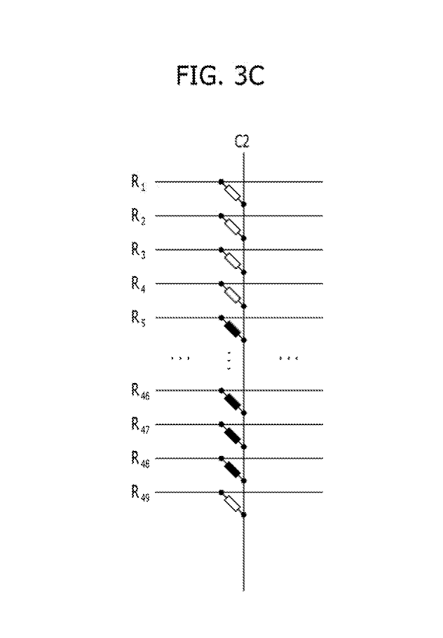

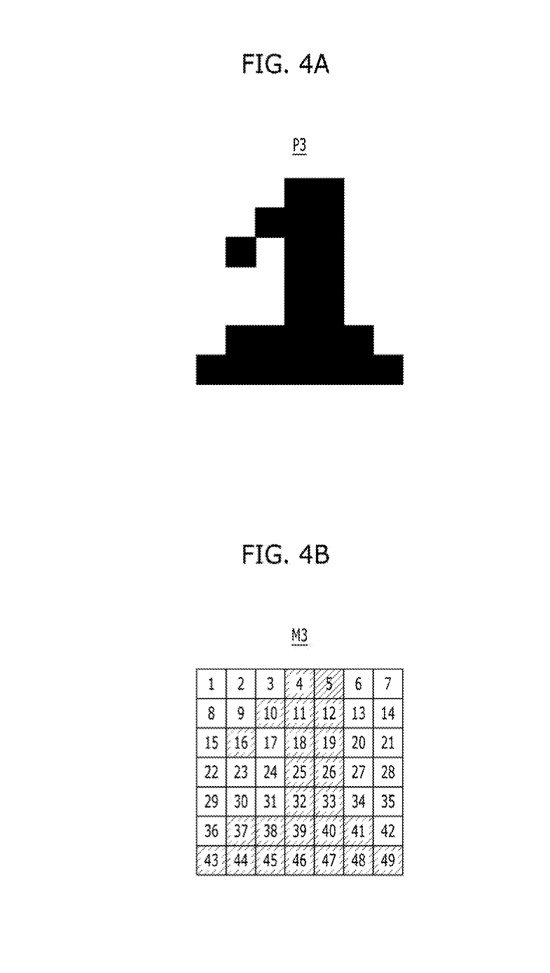

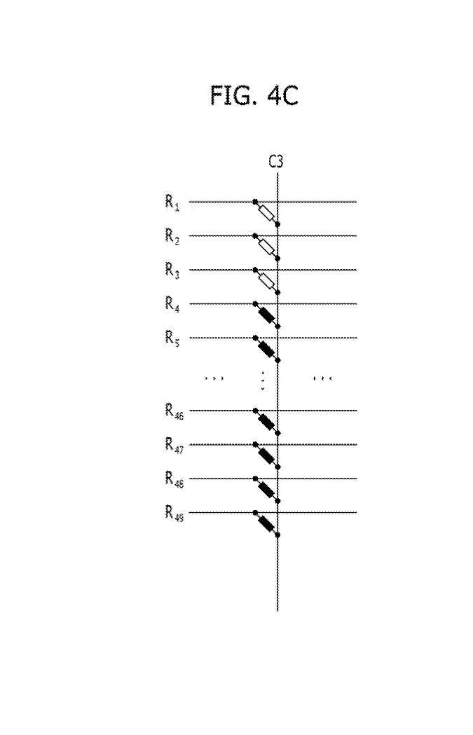

Referring to FIGS. 3A to 3C, the second input pattern P2 may be computed into the second synaptic weight map M2, and the second synaptic weight map M2 is programmed to the second synapse column C2. Referring to FIGS. 4A to 4C, the third input pattern P3 may be computed into the third synaptic weight map M3, and the third synaptic weight map M3 is programmed into the third synapse column C3.

In an embodiment, the input patterns P1 to P3 may include color images or images having multi-contrasts and colors. In expanded embodiments, the input patterns P1 to P3 may include a variety of auditory data. Thus, the synaptic weights and the fixed resistance values may have multiple levels.

In an embodiment, each synaptic weight of each cell may represent information corresponding to one of more than two logic values. For example, the more than two logic values may include a first logic value corresponding to a first synaptic weight, a second logic value corresponding to a second synaptic weight, and a third logic value corresponding to a third synaptic weight. The first synaptic weight may represent a patterned portion, the second synaptic weight may represent a non-patterned portion, and the third synaptic weight may represent a boundary portion between the patterned portion and the non-patterned portion. The boundary portion may include both a part of the patterned portion and a part of the non-patterned portion. Therefore, in this embodiment, a synaptic column may include synapses programmed into three different fixed resistance values respectively corresponding to the first to third synaptic weights.

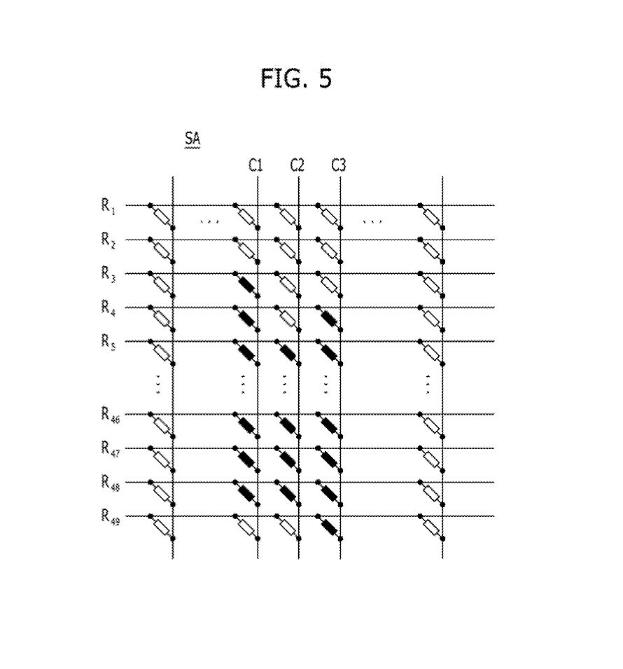

FIG. 5 schematically illustrates a final synapse array SA including final, programmed synapses. Referring to FIG. 5, the final synapse array SA may include the synapse columns C1 to C3 that are programmed with the synaptic weights of the first to third synaptic weight maps M1 to M3. The first to third synaptic weight maps M1 to M3 may correspond to the first to third input patterns P1 to P3. Specifically, the final synapse array SA may include information on the input patterns P1, P2, and P3 that are programmed into the synapses arranged on the synapse columns C1, C2, and C3, which are illustrated in FIGS. 2C, 3C, and 4C, respectively. FIG. 5 shows only three programmed synapse columns C1 to C3, but the synapse array SA may have information on various input patterns corresponding to the number of column lines C included in the synapse array SA.

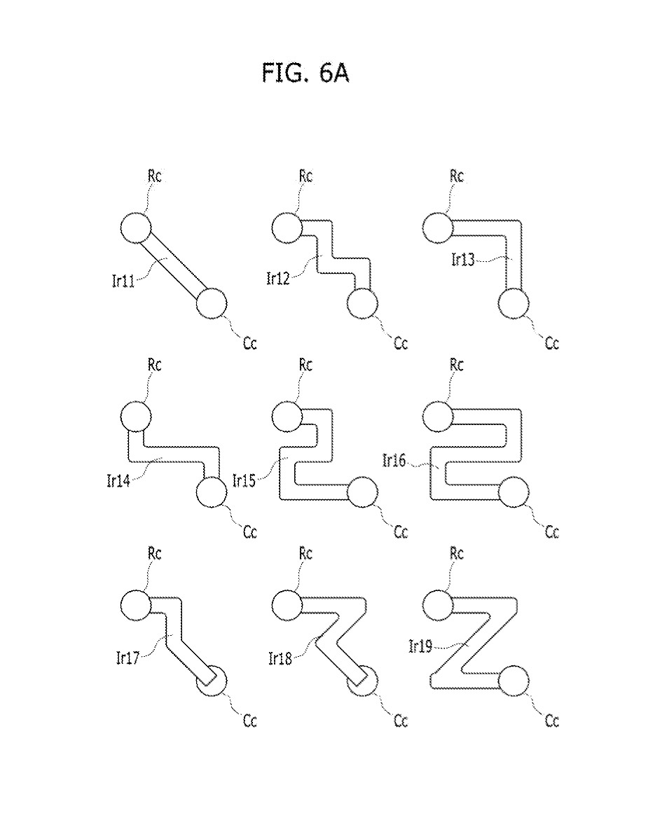

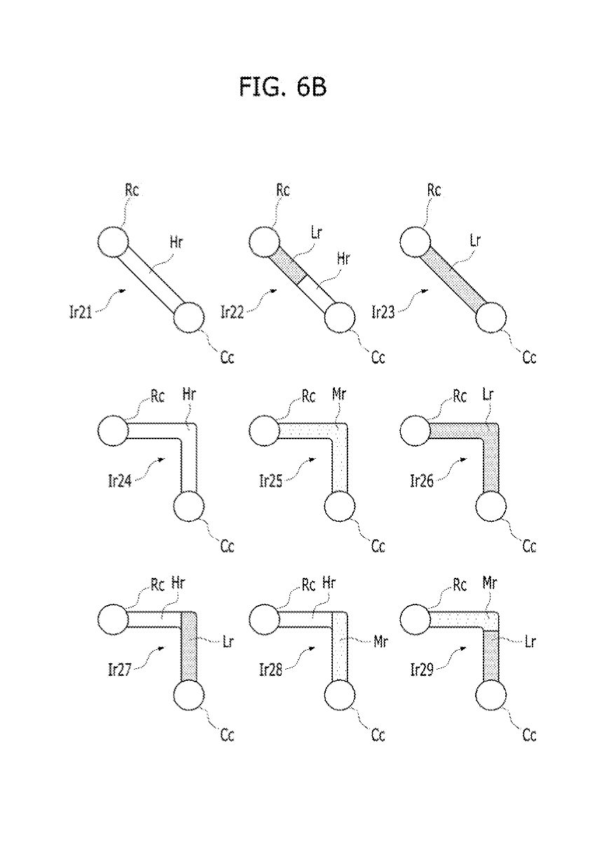

FIGS. 6A to 6D are diagrams illustrating methods for implementing synapses having various fixed resistance values in accordance with various embodiments.

FIG. 6A illustrates conceptual layouts or plan views of synapses having various fixed resistance values in accordance with embodiments. Referring to FIG. 6A, each of the synapses may include a row contact Rc, a column contact Cc, and a resistor interconnection Ir.

The resistor interconnection Ir of each synapse may electrically connect the row contact Rc and the column contact Cc of the synapse. The row contact Rc may be electrically connected to one of row lines R, and the column contact Cc may be electrically connected to one of column lines C. The resistor interconnections Ir11 to Ir19 shown in FIG. 6A may have a variety of geometrical shapes and have various lengths according to the geometrical shapes. A fixed resistance value of each of the resistor interconnections Ir11 to Ir19 may be based on a length of each of the resistor interconnections Ir11 to Ir19. Therefore, the fixed resistance value of each synapse depends on the geometrical shape of the corresponding resistor interconnection Ir11 to Ir19, since the resistor interconnections Ir11 to Ir19 resemble strips having substantially the same width but different lengths.

For example, a resistor interconnection Ir of a synapse having a synaptic weight of “1” may have a relatively short length that corresponds to a relatively low resistance value. If a very high resistance value is required, a resistor interconnection Ir may be cut or may be omitted between a row contact Rc and a column contact Cc, such that the row contact Rc is electrically separate from the column contact Cc. In another embodiment, the resistor interconnection Ir may have different widths. Specifically, a low resistor value of the resistor interconnection Ir may have a relatively wider width and a higher resistor interconnection Ir may have a relatively narrower width.

The resistor interconnection Ir may be formed in a silicon substrate. For example, the resistor interconnection Ir may be provided in the form of a silicon wiring, a metal silicide interconnection, or a metal interconnection, which is doped with N-type ions such as P (phosphorous) ions or As (arsenic) ions. The resistor interconnection Ir may be a part of the silicon substrate.

FIG. 6B illustrates conceptual layouts or plan views of synapses having various fixed resistance values in accordance with embodiments. Referring to FIG. 6B, the synapses may have various conductivities, such that resistor interconnections Ir21 to Ir29 have various lengths and resistance values depending on the synaptic weight of the corresponding synapse. In contrast, the synapses illustrated in FIG. 6A have substantially the same conductivity and include the resistor interconnections Ir11 to Ir19 having different lengths.

Specifically, referring to FIG. 6B, each of the resistor interconnections Ir21 to Ir29 may have a high-resistance region Hr, a middle-resistance region Mr, a low-resistance region Lr, or one of combinations thereof. The high-resistance region Hr, the middle-resistance region Mr, and the low-resistance region Lr may have different doping concentrations. In an embodiment, each of the resistor interconnections Ir21 to Ir29 may include one or more silicon regions having a variety of doping concentrations.

Accordingly, although the resistor interconnections may have the same shape, the resistor interconnections may have different resistance values. For example, the resistor interconnections Ir 21 to Ir23 may have the same shape, but may have different resistance values since the resistor interconnection Ir21 includes the high-resistance region Hr only, the resistor interconnection Ir23 includes the low-resistance region Lr only, and the resistor interconnection Ir22 includes a combination of the high-resistance region Hr and the low-resistance region Lr.

In another example, although the resistor interconnections Ir24 to Ir26 have the same shape, the resistor interconnections Ir24 to Ir26 may have different resistance values since the resistor interconnection Ir24 includes the high-resistance region Hr only, the resistor interconnection Ir25 includes the middle-resistance region Mr only, and the resistor interconnection Ir26 includes the low-resistance region Lr only.

In still another example, although the resistor interconnections Ir27 to Ir29 have the same shape, the resistor interconnections Ir27 to Ir29 may have different resistance values since the resistor interconnection Ir27 includes a combination of the high-resistance region Hr and the low-resistance region Lr, the resistor interconnection Ir28 includes a combination of the high-resistance region Hr and the middle-resistance region Mr, and the resistor interconnection Ir29 includes a combination of the middle-resistance region Mr and the low-resistance region Lr.

Therefore, although resistor interconnections have the same shape, the resistor interconnections can have different fixed resistance values by selectively including a plurality of regions having different doping concentrations.

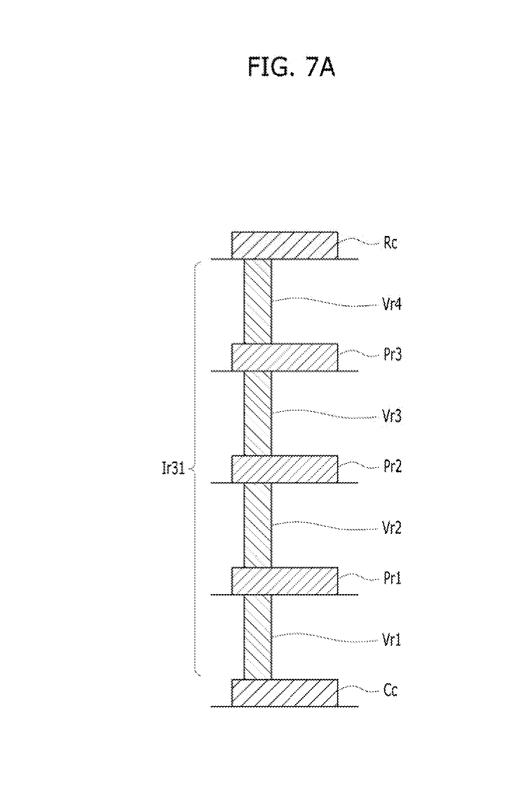

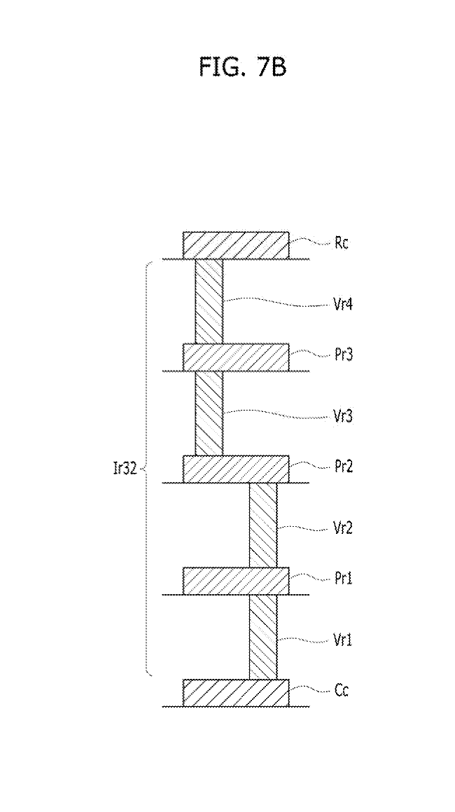

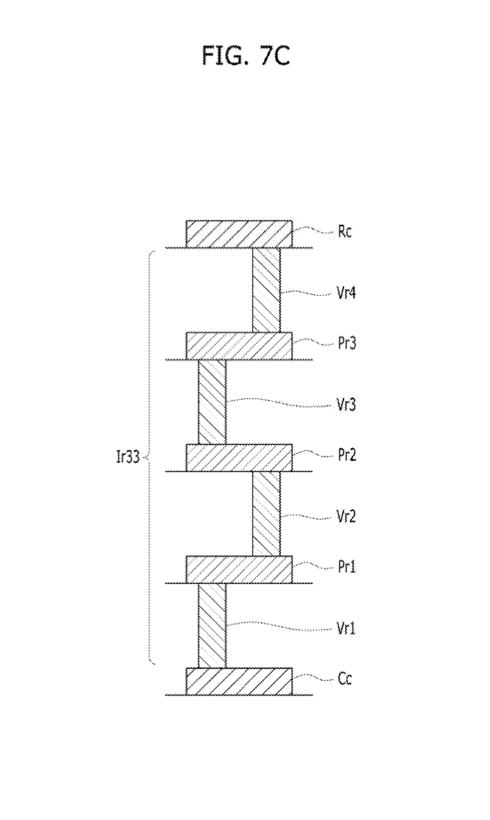

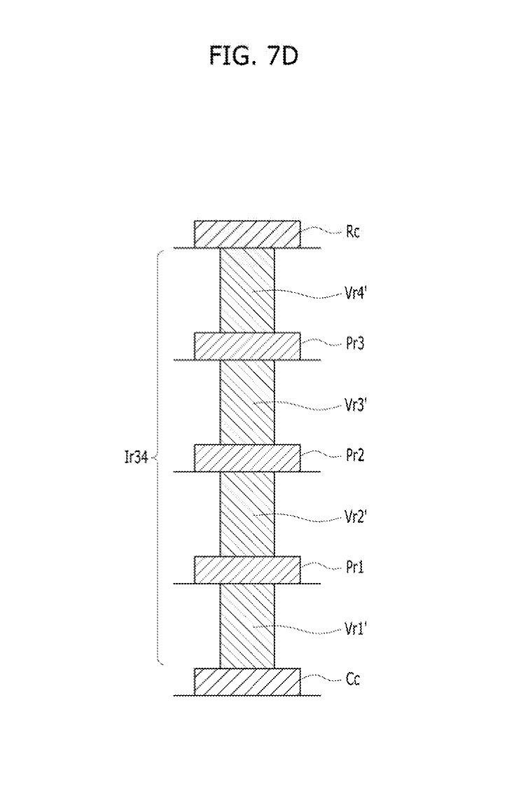

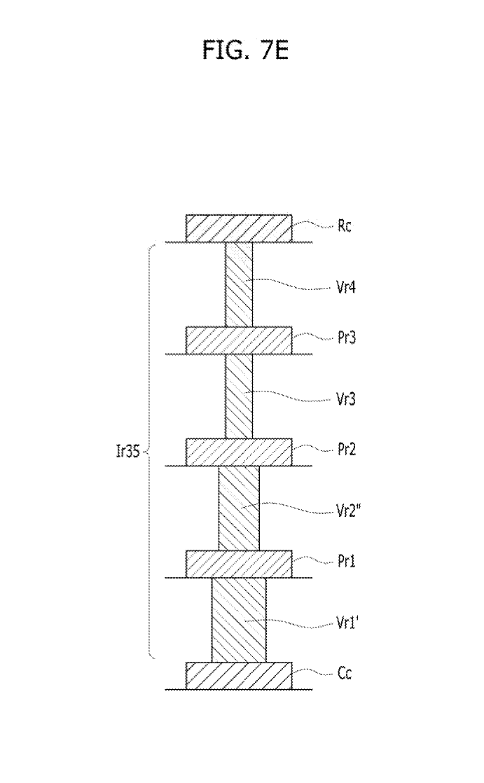

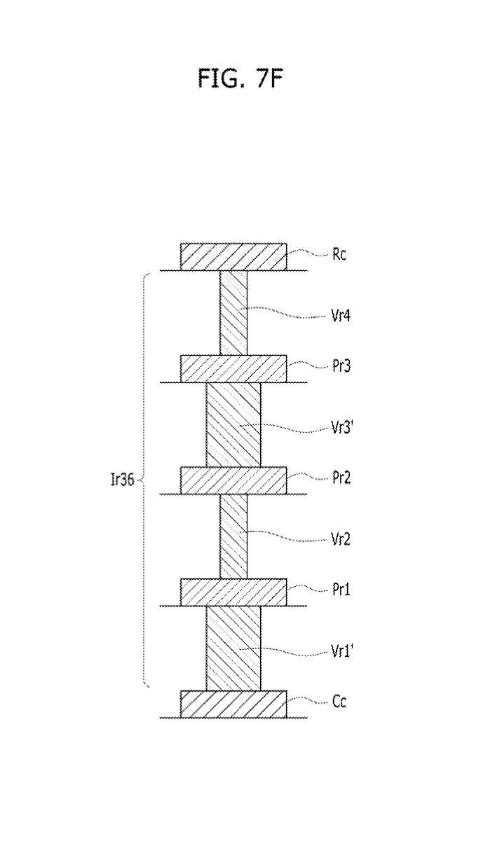

FIGS. 7A to 7C illustrate longitudinal cross-sectional views of synapses having fixed resistance values in accordance with embodiments. Referring to FIGS. 7A to 7C, each of the synapses may include a row contact Rc, a column contact Cc, and a resistor interconnection Ir. The resistor interconnection Ir of each synapse may electrically connect the row contact Rc and the column contact Cc. The row contact Rc and the column contact Cc may be parts of a row line R and a column line C, respectively.

The resistor interconnection Ir may include a plurality of via plugs Vr1 to Vr4 and a plurality of pads Pr1 to Pr3, which are alternately disposed. With respect to the orientation of FIGS. 7A to 7C, the via plugs Vr1 to Vr4 extend in a vertical direction and are disposed at different vertical levels, and the pads Pr1 to Pr3 extend in a horizontal direction. The via plugs Vr1 to Vr4 may each have a pillar shape and may have substantially the same horizontal width or thickness. The pads Pr1 to Pr3 may have a rectangular shape or bar shape when viewed in a plan view.

The via plugs Vr1 to Vr4 may have various geometrical structures in which they are vertically aligned with each other or not aligned with each other such that the resistor interconnection Ir can have one of various fixed resistance values according to the alignment of the via plugs Vr1 to Vr4. That is, the resistor interconnection Ir may have one of various fixed resistance levels determined by various conductive paths that are formed by the via plugs Vr1 to Vr4 and the pads Pr1 to Pr3.

For example, in FIG. 7A, the via plugs Vr1 to Vr4 are vertically aligned with each other. In contrast, in FIG. 7C, the via plugs are not vertically aligned with each other, e.g., Vr2 is not vertically aligned with adjacent via plugs Vr1 and Vr3. The resistor interconnection Ir31 shown in FIG. 7A therefore has a shorter conductive path than the resistor interconnection Ir33 shown in FIG. 7C. Therefore, the resistor interconnection Ir31 shown in FIG. 7A may have a lower resistance value than the resistor interconnection Ir33 shown in FIG. 7C.

Meanwhile, in a resistor interconnection Ir32 shown in FIG. 7B, the via plugs Vr1 and Vr2 are vertically aligned with each other and the via plugs Vr3 and Vr4 are vertically aligned with each other, but the via plugs Vr1 and Vr2 are not vertically aligned with the via plugs Vr3 and Vr4. Therefore, the resistor interconnection Ir32 shown in FIG. 7B may have a conductive path that is longer than the conductive path of the resistor interconnection Ir31 and shorter than the conductive path of the resistor interconnection Ir33. Thus, the resistor interconnection Ir32 may have a resistance value between the resistance value of the resistor interconnection Ir31 and the resistance value of the resistor interconnection Ir33.

FIGS. 7A to 7C illustrate four via plugs Vr1 to Vr4 that are vertically stacked in each of the resistor interconnections Ir31 to Ir33. However, in another embodiment, the resistor interconnection Ir may have five or more via plugs that are vertically stacked. As described above, the resistor interconnections Ir may have various fixed resistance values depending on length differences in electrical paths formed between the row contact Rc and the column contact Cc. The via plugs Vr1 to Vr4 and the pads Pr1 to Pr3 may include doped silicon, silicide, a metal, or one of combinations thereof.

FIGS. 7D to 7F illustrate longitudinal cross-sectional views of synapses having various fixed resistance values in accordance with embodiments. Referring to FIGS. 7D to 7F, the synapses may include a plurality of via plugs disposed at different vertical levels and having various horizontal widths or thicknesses, while the via plugs Vr1 to Vr4 of the synapses illustrated in FIGS. 7A to 7C have substantially the same horizontal width or thickness. That is, in the synapses shown in FIGS. 7D to 7F, at least one of via plugs disposed at different vertical levels may have one or more different cross-sectional areas. Thus, the via plugs of the synapses illustrated in FIGS. 7D to 7F may provide various resistance levels or values between the row contact Rc and the column contact Cc.

In FIG. 7D, the synapse includes via plugs Vr1′, Vr2′, Vr3′, and Vr4′, which have substantially the same horizontal width or thickness and are vertically aligned with each other. In FIG. 7E, the synapse includes via plugs Vr1′, Vr2″, Vr3, and Vr4, which have different horizontal widths or thicknesses. In FIG. 7F, the synapse includes via plugs Vr1′, Vr2, Vr3′, and Vr4, which have different horizontal widths or thicknesses. In FIGS. 7D to 7F, the via plug Vri′, e.g., Vr2′, has a greater width or thickness than the via plug Vri, e.g., Vr2; and the via plug Vri″, e.g., Vr2″, has a width or thickness between the width or thickness of the via plug Vr2 and the width or thickness of the via plug Vr2′, i being in a range of 1 to 4. Because the via plug Vri′ has a greater width or thickness than the via plug Vri, the via plug Vri′ has a higher conductivity and a lower resistance value than the via plug Vri. Therefore, a resistor interconnection Ir34 shown in FIG. 7D has a higher conductivity and a lower resistance value than resistor interconnections Ir35 and Ir36 shown in FIGS. 7E and 7F, since the resistor interconnection Ir34 includes thicker via plugs than the resistor interconnections Ir35 and Ir36.

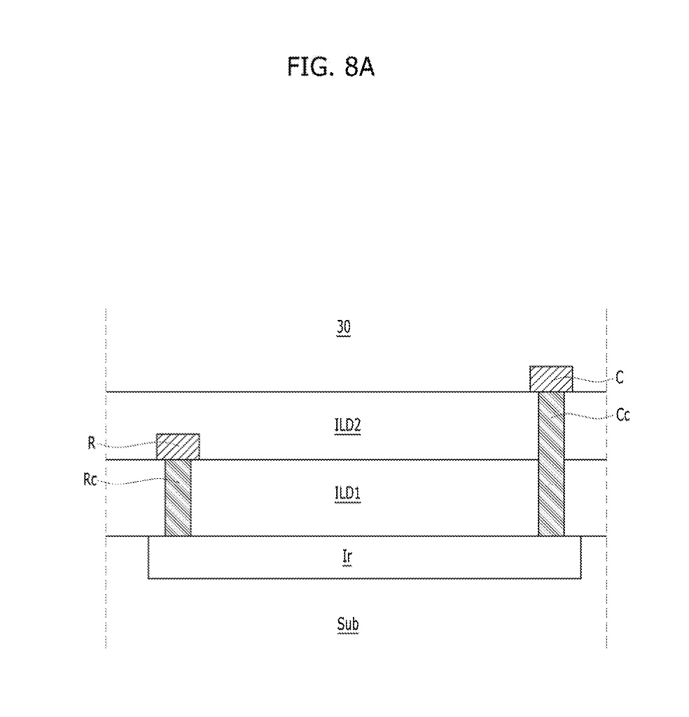

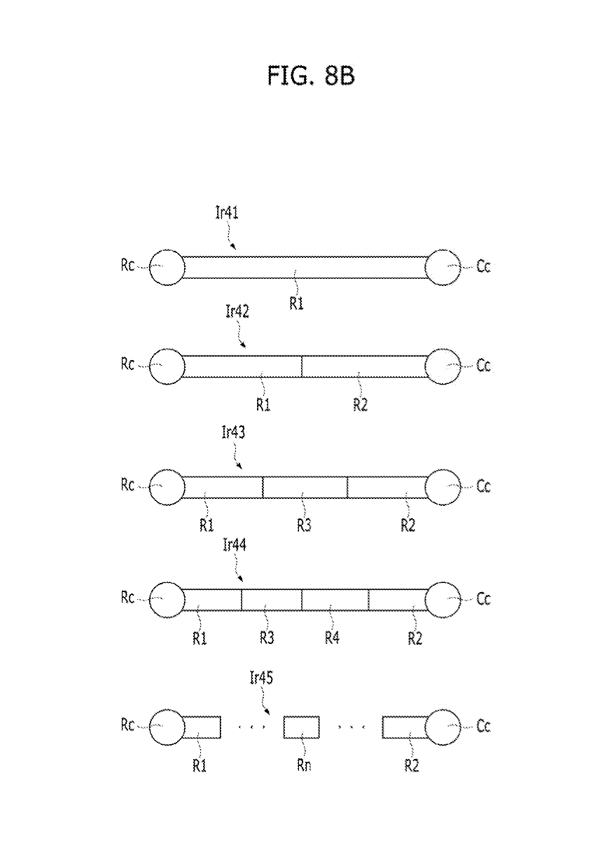

FIG. 8A is a conceptual longitudinal cross-sectional view of a synapse 30 having a fixed resistance value in accordance with an embodiment. FIG. 8B illustrates layouts or plan views of the synapse 30 in accordance with embodiments.

Referring to FIG. 8A, the synapse 30 may include a resistor interconnection Ir, a row contact Rc, and a column contact Cc. The resistor interconnection Ir may be formed in a substrate Sub. The row contact Rc and the column contact Cc may be formed on the substrate Sub. The row contact Rc may be electrically coupled to and disposed between the resistor interconnection Ir and a row line R, and may penetrate through a first interlayer dielectric layer ILD1. The column contact Cc may be electrically coupled to and disposed between the resistor interconnection Ir and a column line C, and may penetrate through the first and second interlayer dielectric layers ILD1 and ILD2. The column line C is disposed over the row line R.

In another embodiment, the positions of the row line R and the row contact Rc may be exchanged with the positions of the column line C and the column contact Cc. That is, the row contact Rc may be formed to penetrate through the first and second interlayer dielectric layers ILD1 and ILD2, the column contact Cc may be formed to penetrate through the first interlayer dielectric layer ILD1, and the row line R may be disposed over the column line C.

Referring to FIG. 8B, synapses in accordance with embodiments may include resistor interconnections Ir41 to Ir45 including various conductive materials. For example, each of the resistor interconnections Ir41 to Ir45 may include combinations of various resistance regions R₁ to Rₙ, n being a positive integer larger than 1. For example, each of the various resistance regions R₁ to Rₙ of the resistor interconnections Ir41 to Ir45 may include one of an intrinsic semiconductor region, a low-concentration doped semiconductor region, a high-concentration doped semiconductor region, a metal silicide region, a metal compound region, a metal alloy region, and a metal region. Due to the compositions of the various resistance regions R₁ to Rₙ, each of the resistor interconnections Ir41 to Ir45 may selectively have one of multiple resistance levels.

For example, the resistor interconnection Ir41 includes the resistance region R₁ only, and the resistor interconnection Ir45 includes the resistance regions R₁ to Rₙ. Therefore, the resistor interconnection Ir41 has a different resistance level than the resistor interconnection Ir45.

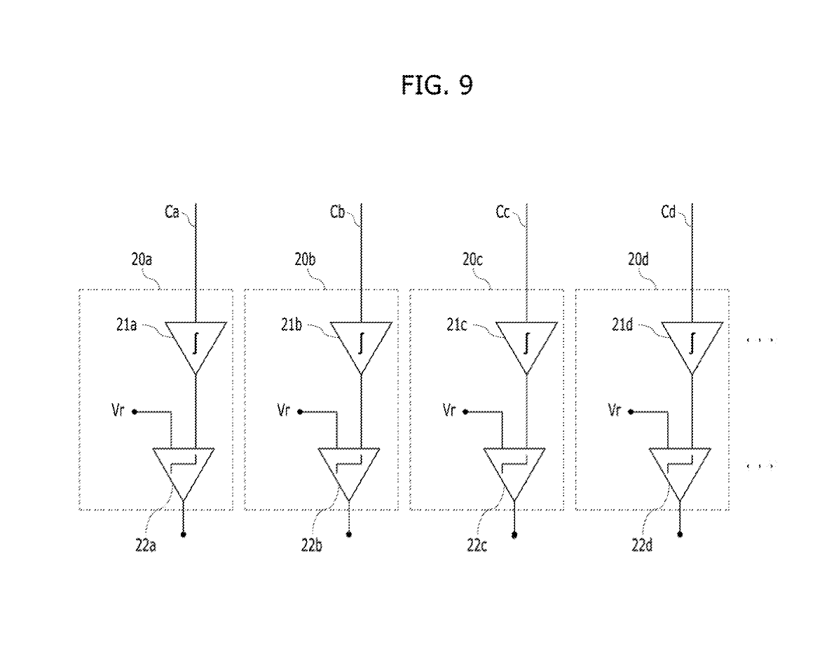

FIG. 9 is a block diagram conceptually illustrating post-synaptic neurons 20 in accordance with an embodiment.

Referring to FIG. 9, the post-synaptic neurons 20 may include post-synaptic circuits 20a to 20d which are independently connected to column lines Ca to Cd, respectively. Each of the post-synaptic circuits 20a to 20d may include a corresponding one of integrators 21a to 21d and a corresponding one of comparators 22a to 22d. Specifically, each of the integrators 21a to 21d may have an input unit, which is electrically connected to a corresponding one of the column lines Ca to Cd. Each of the comparators 22a to 22d may receive an output of a corresponding one of the integrators 21a to 21d. The post-synaptic circuits 20a to 20d may integrate electrical signals received from the respective synapses 30 through the corresponding column lines Ca to Cd, respectively. When a voltage of the integrated electrical signal becomes higher than a reference voltage Vr, the post-synaptic neuron 20 may fire.

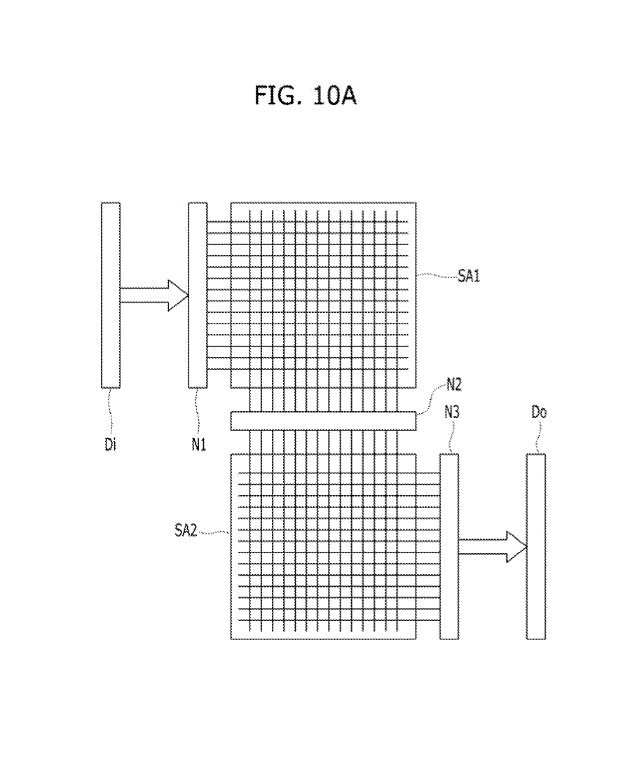

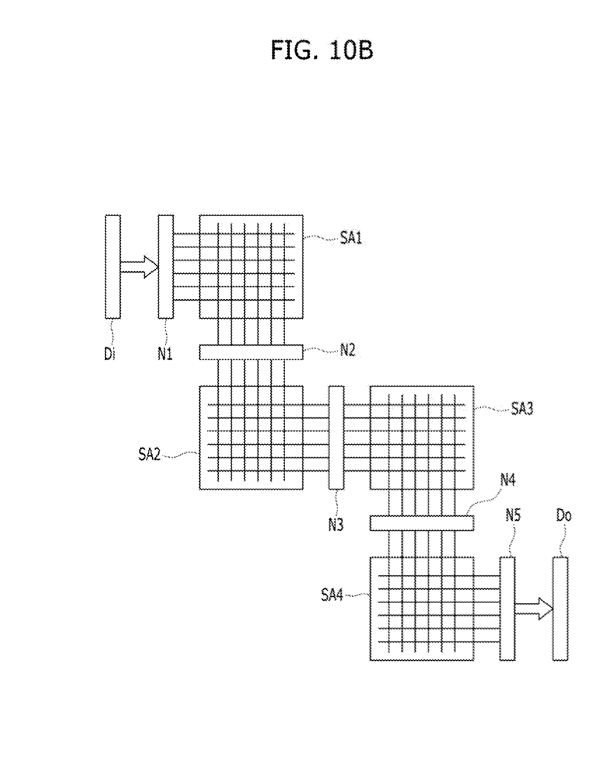

FIGS. 10A and 10B are block diagrams conceptually illustrating multi-neuromorphic systems in accordance with various embodiments. Referring to FIGS. 10A and 10B, the multi-neuromorphic system may include multiple synapse arrays. Specifically, the multi-synapse neuromorphic system may include an input device Di, an output device Do, three or more synaptic neurons N1 to N3 or N1 to N5, and two or more synapse arrays SA1 and SA2 or SA1 to SA4. The synaptic neurons N1 to N3 or N1 to N5 and the synapse arrays SA1 and SA2 or SA1 to SA4 are alternately connected between the input device Di and the output device Do. For example, in FIG. 10A, the components are sequentially connected in series in an order of Di, N1, SA1, N2, SA2, N3, and Do. In FIG. 10B, the components are sequentially connected in series in an order of Di, N1, SA1, N2, SA2, N3, SA3, N4, SA4, N5, and Do.

The input device Di may include at least one of an image sensor, a scanner, a mouse, a touch panel, a touch pen, a microphone, a sound receiver, a sampler, or another recognition device. Each of the synaptic neurons N1 to N5 may include pre-synaptic neurons or post-synaptic neurons. The first synaptic neuron N1 may include a pre-processor capable of changing an input pattern to a digital signal, such as an image processor or a sound processor. The synapse arrays SA1 to SA4 may include one or more of the final synapse arrays SA in accordance with the various embodiments. That is, one or more of the synapse arrays SA1 to SA4 may include the synapses having fixed resistance values. The neuromorphic systems including the multiple synapse arrays SA1 to SA4 in accordance with the embodiments may provide various data patterns which are not provided by one synapse array. The neuromorphic systems including the multiple synapse arrays SA1 to SA4 can more accurately recognize complex data patterns.

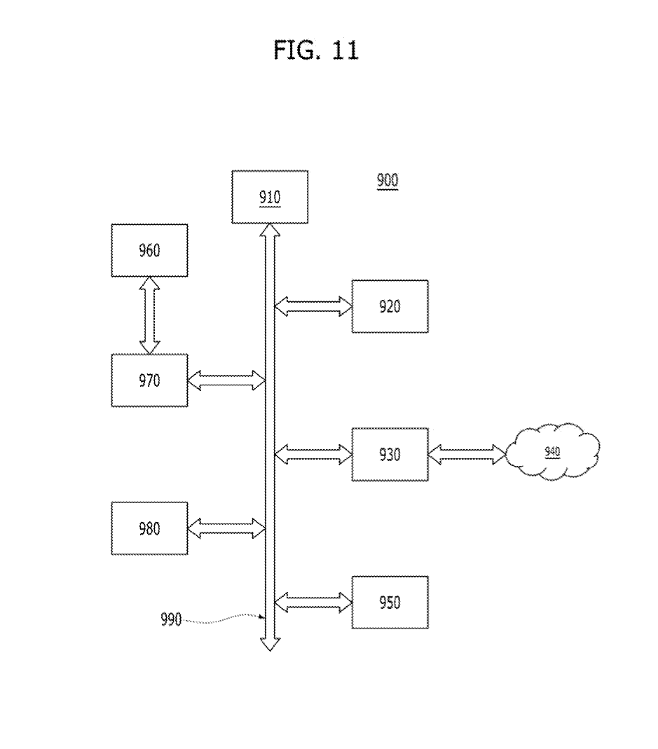

FIG. 11 is a block diagram conceptually illustrating a pattern recognition system 900 in accordance with an embodiment. For example, the pattern recognition system 900 may include any of a speech recognition system, an imaging recognition system, a code recognition system, a signal recognition system, and a system for recognizing various patterns.

Referring to FIG. 11, the pattern recognition system 900 may include a CPU 910, a memory unit 920, a communication control unit 930, a network 940, an output unit 950, an input unit 960, an ADC (Analog-Digital Converter) 970, a neuromorphic unit 980, and a bus 990. The CPU 910 may generate and transmit various signals for training the neuromorphic unit 980, and perform various processes and functions for recognizing patterns such as speech and images according to an output from the neuromorphic unit 980.

The CPU 910 may be connected to the memory unit 920, the communication control unit 930, the output unit 950, the ADC 970, and the neuromorphic unit 980 through the bus 990.

The memory unit 920 may store various pieces of information in accordance with operations of the pattern recognition system 900. The memory unit 920 may include one or more of a volatile memory device such as DRAM or SRAM, a nonvolatile memory such as PRAM, MRAM, ReRAM, or NAND flash memory, and a storage unit such as an HDD (Hard Disk Drive) and an SSD (Solid State Drive).

The communication control unit 930 may transmit and/or receive data, such as recognized speech and images, to and/or from a communication control unit of another system through the network 940.

The output unit 950 may output the data such as the recognized speech and images in various manners. For example, the output unit 950 may include one or more of a speaker, a printer, a monitor, a display panel, a beam projector, a hologrammer, and so on.

The input unit 960 may include one or more of a microphone, a camera, a scanner, a touch pad, a keyboard, a mouse, a mouse pen, a sensor, and so on.

The ADC 970 may convert analog data transmitted from the input unit 960 into digital data.

The neuromorphic unit 980 may perform learning or recognition using the data transmitted from the ADC 970, and may output data corresponding to recognized patterns. The neuromorphic unit 980 may include one or more of the neuromorphic devices in accordance with the various embodiments.

In accordance with the embodiments, since synapses have fixed resistance values, it is possible to provide a neuromorphic device having various data patterns without training the synapses.

Furthermore, since synapses have fixed resistance values, it is possible to provide a neuromorphic device which includes synapses with excellent data retention ability.

Moreover, since synapses are formed of a cheap fixed resistance material instead of an expensive variable resistance material, the manufacturing cost of a neuromorphic device may be reduced. That is, a neuromorphic device which is optimized for a specific field may be provided at a low price.

Furthermore, a neuromorphic chip having a specific function (classifying a specific pattern) can be manufactured at an integration process.

Moreover, since synapses have fixed resistance values in accordance with an embodiment, peripheral circuits, which induce and detect variable resistance values in a neuromorphic device that includes synapses having variable resistance values, can be omitted. Thus, a neuromorphic device that includes the synapses having fixed resistance values may be reduced in size.

Furthermore, the number of data patterns which can be recognized by synapses of a neuromorphic device may be increased.

Moreover, the recognition accuracy for complex patterns of a neuromorphic device may be improved.

Although various embodiments have been described for illustrative purposes, it will be apparent to those skilled in the art that various changes and modifications may be made without departing from the spirit and scope of the invention as defined in the following claims.

What is claimed is:

1. A neuromorphic device comprising:
pre-synaptic neurons;
row lines extending in a first direction from the pre-synaptic neurons, respectively;
post-synaptic neurons;
column lines extending in a second direction from the post-synaptic neurons, respectively, the second direction crossing the first direction; and
synapses arranged in intersection regions between the row lines and the column lines,
wherein the synapses comprise resistor interconnections having various fixed resistance values, the synapses being programmed with at least one pattern based on the various fixed resistance values.

2. The neuromorphic device of claim 1, wherein the various fixed resistance values include at least four levels.

3. The neuromorphic device of claim 1, wherein the resistor interconnections are disposed in a substrate.

4. The neuromorphic device of claim 1, wherein the synapses comprise resistor interconnections that include conductive paths having different lengths, the different lengths respectively providing the various fixed resistance values.

5. The neuromorphic device of claim 1, wherein the synapses comprise resistor interconnections that contain ions doped at various concentrations, the various concentrations providing the various fixed resistance values.

6. The neuromorphic device of claim 5, wherein the resistor interconnections comprise silicon doped with N-type or P-type ions.

7. The neuromorphic device of claim 6, wherein the resistor interconnections are doped with N-type ions, the N-type ions including P (phosphorous) or As (arsenic) ions.

8. The neuromorphic device of claim 5, wherein each of the resistor interconnections comprises one or more doping regions having different doping concentrations.

9. The neuromorphic device of claim 8, wherein each of the resistor interconnections comprises one or more of a low-concentration doping region, a middle-concentration doping region, and a high-concentration doping region.

10. The neuromorphic device of claim 1, wherein each of the resistor interconnections comprises one or more resistance regions having different conductivities.

11. The neuromorphic device of claim 10, wherein each of the resistance regions includes one of an intrinsic semiconductor region, a low-concentration doped semiconductor region, a high-concentration doped semiconductor region, a metal silicide region, a metal compound region, a metal alloy region, and a metal region.

12. The neuromorphic device of claim 1, wherein each of the resistor interconnections is a silicon wiring, a metal silicide interconnection, or a metal interconnection.

13. The neuromorphic device of claim 1, wherein each of the synapses further comprises a row contact and a column contact, and wherein the resistor interconnection electrically connects the row contact and the column contact.

14. The neuromorphic device of claim 1, wherein each of the resistor interconnections comprises a plurality of via plugs that are electrically coupled to each other.

15. The neuromorphic device of claim 14, wherein the resistor interconnection further comprises a plurality of pads that are alternately stacked with the plurality of via plugs.

16. The neuromorphic device of claim 15, wherein the plurality of via plugs provides the various fixed resistance levels by having different vertical alignments.

17. The neuromorphic device of claim 15, wherein the plurality of via plugs provides the various fixed resistance levels by having different horizontal thicknesses.

18. The neuromorphic device of claim 1, wherein the post-synaptic neurons comprise post-synaptic circuits that are electrically connected to the column lines, respectively, each of the post-synaptic neurons comprising an integrator and a comparator, the integrator having an input unit connected to a corresponding one of the column lines, the comparator receiving an output of the integrator.

19. The neuromorphic device of claim 1, wherein the synapses coupled to one of the column lines are programmed to store a different pattern from synapses coupled to another one of the column lines.
